(19) United States
(12) Patent Application Publication
(10) Pub. No.: US 2012/0070928 A1
(43) Pub. Date: Mar. 22, 2012

(54) THIN FILM DEPOSITION APPARATUS AND METHOD OF MANUFACTURING ORGANIC LIGHT-EMITTING DISPLAY DEVICE BY USING THE SAME

(76) Inventors: Jung-Yeon Kim, Yongin-city (KR); Beom-Rak Choi, Yongin-city (KR)

(21) Appl. No.: 13/235,337

(22) Filed: Sep. 16, 2011

(30) Foreign Application Priority Data
Sep. 17, 2010 (KR) 10-2010-0092011

(51) Int. Cl. H01L 33/02; B05C 11/00; B05C 5/00

(52) U.S. Cl. 438/34; 118/300; 257/E33.013

(57) ABSTRACT

A thin film deposition apparatus for forming a thin film on a substrate includes: a deposition source for discharging a deposition material; a deposition source nozzle unit having a plurality of nozzles arranged in a first direction; a patterning slit sheet located opposite to the deposition source and having a plurality of patterning slits arranged in the first direction; and a barrier plate assembly including a plurality of barrier plates that are arranged between the deposition source nozzle unit and the patterning slit sheet in the first direction to partition a space between the deposition source nozzle unit and the patterning slit sheet into a plurality of sub-deposition spaces. The thin film deposition apparatus and the substrate are movable relative to each other in a movement direction that has an angle greater than about 90° and less than about 180° with respect to the first direction.

### CROSS-REFERENCE TO RELATED APPLICATION

This application claims priority to and the benefit of Korean Patent Application No. 10-2010-0092011, filed Sep. 17, 2010, in the Korean Intellectual Property Office, the disclosure of which is incorporated herein in its entirety by reference.

### BACKGROUND

1. Field

The present invention relates to a thin film deposition apparatus and a method of manufacturing an organic light-emitting display device by using the same.

2. Description of Related Art

Organic light-emitting display devices typically have a larger viewing angle, better contrast characteristics, and faster response speeds than other display devices, and thus have drawn attention as next-generation display devices.

Organic light-emitting display devices generally have a stacked structure including an anode, a cathode, and an emission layer interposed between the anode and the cathode. The organic light-emitting display devices can display images in color when holes and electrons, injected respectively from the anode and the cathode, recombine in the emission layer, and thereby inducing the emission layer to emit light. However, it is difficult to achieve a high light-emission efficiency with such a structure, and thus intermediate layers, including an electron injection layer, an electron transport layer, a hole transport layer, a hole injection layer, etc., are optionally additionally interposed between the emission layer and a respective one of the electrodes.

The electrodes and the intermediate layers of an organic light-emitting display device may be formed via various methods, one of which is a deposition method. When an organic light-emitting display device is manufactured using a conventional deposition method, a fine metal mask (FMM) having the same pattern as a thin layer to be formed is positioned to closely contact a substrate, and a thin film material is deposited over the FMM in order to form the thin layer having a desired pattern.

In practice, it is very difficult to form fine patterns on organic thin films such as the emission layer and the intermediate layers, and red, green, and blue light-emission efficiency varies according to the organic thin films. For these reasons, it is not easy to form an organic thin film pattern on a large substrate, such as a mother glass having a size of 5G or more, by using a conventional thin film deposition apparatus, and thus it is difficult to manufacture large organic light-emitting display devices having satisfactory driving voltage, current density, brightness, color purity, light-emission efficiency, and life-span characteristics. Thus, improvement in this regard is desired.

### SUMMARY

Embodiments of the present invention provide a thin film deposition apparatus that may be easily manufactured, that may be applied to manufacture large-size display devices on a mass scale in a simple fashion, that may improve manufacturing yield and deposition efficiency, that may allow deposited materials to be reused, and that may improve uniformity in thickness of deposited thin films, and a method of manufacturing an organic light-emitting display device by using the thin film deposition apparatus.

According to an aspect of embodiments of the present invention, a thin film deposition apparatus for forming a thin film on a substrate includes: a deposition source for discharging a deposition material; a deposition source nozzle unit located at a side of the deposition source and having a plurality of deposition source nozzles arranged in a first direction; a patterning slit sheet located opposite to the deposition source and having a plurality of patterning slits arranged in the first direction; and a barrier plate assembly including a plurality of barrier plates that are arranged between the deposition source nozzle unit and the patterning slit sheet in the first direction, the barrier plate assembly partitioning a space between the deposition source nozzle unit and the patterning slit sheet into a plurality of sub-deposition spaces, wherein the thin film deposition apparatus and the substrate are movable relative to each other, and a relative movement direction between the substrate and the thin film deposition apparatus is at an angle greater than about 90° and less than about 180° with respect to the first direction.

A lengthwise direction of the patterning slits may be substantially the same as a lengthwise direction of the barrier plates.

A lengthwise direction of the barrier plates may be substantially perpendicular to the first direction.

A lengthwise direction of the barrier plates may be at an angle greater than about 0° and less than about 180° with respect to the first direction.

A lengthwise direction of the patterning slits may be substantially perpendicular to the first direction.

A lengthwise direction of the patterning slits may be substantially the same as the movement direction of the substrate.

A lengthwise direction of the patterning slits may be at an angle greater than about 90° and less than about 180° with respect to the first direction.

Each of the barrier plates may extend in a second direction that is substantially perpendicular to the first direction to partition the space between the deposition source nozzle unit and the patterning slit sheet into the plurality of sub-deposition spaces.

The plurality of barrier plates may be arranged at equal intervals.

The barrier plates and the patterning slit sheet may be spaced from each other.

The barrier plate assembly may include a first barrier plate assembly including a plurality of first barrier plates, and a second barrier plate assembly including a plurality of second barrier plates.

Each of the first barrier plates and each of the second barrier plates may extend in a second direction that is substantially perpendicular to the first direction, to partition the space between the deposition source nozzle unit and the patterning slit sheet into the plurality of sub-deposition spaces.

The first barrier plates may be arranged to respectively correspond to the second barrier plates.

Each pair of corresponding said first and second barrier plates may be arranged in substantially the same plane.

According to another aspect of embodiments according to the present invention, a method of manufacturing an organic light-emitting display device by using a thin film deposition apparatus for forming a thin film on a substrate includes: arranging the substrate to be spaced from the thin film deposition apparatus; and depositing a deposition material discharged from the thin film deposition apparatus onto the substrate while the thin film deposition apparatus or the substrate is moved relative to the other, wherein the thin film deposition apparatus comprises: a deposition source that discharges a deposition material; and a deposition source nozzle unit located at a side of the deposition source and having a plurality of deposition source nozzles arranged in a first direction, and wherein a relative movement direction between the substrate and the thin film deposition apparatus is at an angle greater than about 90° and less than about 180° with respect to the first direction.

The depositing of the deposition material on the substrate may further include continuously depositing the deposition material discharged from the thin film deposition apparatus on the substrate while the substrate or the thin film deposition apparatus is moved relative to the other.

The thin film deposition apparatus may further include: a patterning slit sheet located opposite to the deposition source and having a plurality of patterning slits arranged in the first direction; and a barrier plate assembly including a plurality of barrier plates that are arranged between the deposition source nozzle unit and the patterning slit sheet in the first direction, the barrier plate assembly partitioning a space between the deposition source nozzle unit and the patterning slit sheet into a plurality of sub-deposition spaces.

A lengthwise direction of the patterning slits may be substantially the same as a lengthwise direction of the barrier plates.

A lengthwise direction of the barrier plates may be substantially perpendicular to the first direction.

A lengthwise direction of the barrier plates may be at an angle greater than about 0° and less than about 180° with respect to the first direction.

A lengthwise direction of the patterning slits may be substantially perpendicular to the first direction.

A lengthwise direction of the patterning slits may be substantially the same as the movement direction of the substrate.

A lengthwise direction of the patterning slits may be at an angle greater than about 90° and less than about 180° with respect to the first direction.

### BRIEF DESCRIPTION OF THE DRAWINGS

The above and other features and aspects of the present invention will become more apparent by describing in detail exemplary embodiments thereof with reference to the attached drawings in which:

FIG. 1 is a schematic plan view of an organic light-emitting display device manufactured by using a thin film deposition apparatus, according to an embodiment of the present invention.

FIG. 2 is a sectional view of a sub-pixel of the organic light-emitting display device illustrated in FIG. 1, according to an embodiment of the present invention;

FIG. 3 is a schematic perspective view of a thin film deposition apparatus according to an embodiment of the present invention;

FIG. 4 is a schematic side view of the thin film deposition apparatus of FIG. 3, according to an embodiment of the present invention;

FIG. 5 is a schematic plan view of the thin film deposition apparatus illustrated in FIG. 3, according to an embodiment of the present invention;

FIG. 6A is a schematic view for describing deposition of a deposition material in the thin film deposition apparatus of FIG. 3, according to an embodiment of the present invention;

FIG. 6B illustrates a shadow zone of a thin film deposited on a substrate when a deposition space is partitioned by barrier plates, as illustrated in FIG. 6A, according to an embodiment of the present invention;

FIG. 6C illustrates a shadow zone of a thin film deposited on the substrate when the deposition space is not partitioned;

FIG. 7 is a schematic plan view illustrating an arrangement of a substrate, a deposition source, and a patterning slit sheet in a thin film deposition apparatus according to an embodiment of the present invention;

FIG. 8 is a graph illustrating a distribution pattern of a thin film deposited on the substrate 400 by using the thin film deposition apparatus of FIG. 7;

FIG. 9 is a schematic plan view of a thin film deposition apparatus according to an embodiment of the present invention in which the movement direction of a substrate is identical to a direction in which a deposition source is disposed;

FIG. 10 is a graph illustrating a distribution pattern of a thin film deposited on the substrate by using the thin film deposition apparatus of FIG. 9;

FIG. 11 is a schematic plan view illustrating an arrangement of a substrate, a deposition source, and a patterning slit sheet in a thin film deposition apparatus according to another embodiment of the present invention;

FIG. 12 is a graph illustrating a distribution pattern of a thin film deposited on a substrate by using the thin film deposition apparatus of FIG. 11; and

FIG. 13 is a schematic perspective view of a thin film deposition apparatus according to another embodiment of the present invention.

### DETAILED DESCRIPTION

The present invention will now be described more fully with reference to the accompanying drawings in which exemplary embodiments of the invention are shown. In the drawings, the thicknesses of layers and regions are exaggerated for clarity. Like reference numerals in the drawings denote like elements, and thus their description will be omitted.

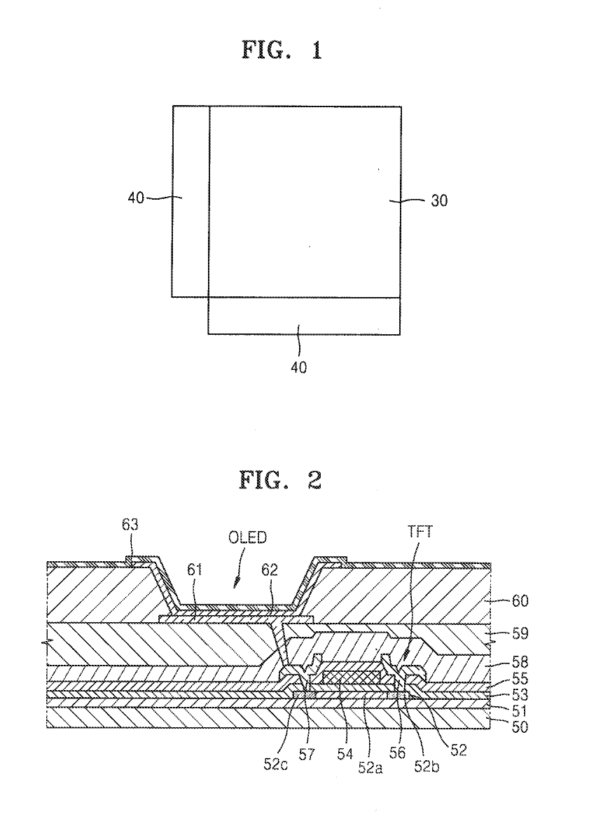

FIG. 1 is a plan view of an organic light-emitting display device manufactured by using a thin film deposition apparatus, according to an embodiment of the present invention.

Referring to FIG. 1, the organic light-emitting display device according to one embodiment includes a display region 30 and circuit regions 40 located at edges of the display region 30. The display region 30 includes a plurality of pixels. Each of the pixels may include an emission unit that emits light to display an image.

In an embodiment of the present invention, the emission unit may include a plurality of sub-pixels, each of which includes an organic light-emitting diode (OLED). In a full-color organic light-emitting display device, red (R), green (G) and blue (B) sub-pixels may be arranged in various patterns, for example, in a line, mosaic, or lattice pattern, to constitute a pixel. The organic light-emitting display device according to the present embodiment, manufactured using a thin film deposition apparatus according to one embodiment of the present invention, may include a monochromatic flat display device.

The circuit regions 40 may control, for example, an image signal that is input to the display region 30. In the organic light-emitting display device according to the present embodiment, at least one thin film transistor (TFT) may be formed in each of the display region 30 and the circuit region 40.

The at least one TFT formed in the display region 30 may include a pixel TFT, such as a switching TFT that transmits a data signal to an OLED according to a gate line signal to control the operation of the OLED, and a driving TFT that drives the OLED by supplying current according to the data signal. The at least one TFT formed in the circuit region 40 may include a circuit TFT constituted to implement a circuit (e.g., a predetermined circuit).

The number and arrangement of TFTs may vary according to the features of the display device and the driving method thereof.

FIG. 2 is a sectional view of a sub-pixel of the organic light-emitting display device illustrated in FIG. 1, according to an embodiment of the present invention.

Referring to FIG. 2, a buffer layer 51 is located on a substrate 50 formed of a transparent or opaque material, for example, glass or plastic. A TFT and an OLED may be located on the buffer layer 51.

An active layer 52 having a pattern (e.g., a predetermined pattern) may be located (e.g., formed) on the buffer layer 51. A gate insulating layer 53 may be located (e.g., formed) on the active layer 52, and a gate electrode 54 may be located (e.g., formed) on the gate insulating layer 53 (e.g., at a predetermined region). The gate electrode 54 may be connected to a gate line via which a TFT ON/OFF signal is applied. An interlayer insulating layer 55 may be located (e.g., formed) on the gate electrode 54. Source/drain electrodes 56 and 57 may be located (e.g., formed) to contact source/drain regions 52a and 52c, respectively, of the active layer 52 through respective contact holes. A passivation layer 58 may be formed of SiO₂, SiNₓ, or the like on the source/drain electrodes 56 and 57. A planarization layer 59 may be formed of an organic material, such as acryl, polyimide, benzocyclobutene (BCB), or the like on the passivation layer 58. A pixel electrode 61, which operates as an anode of the OLED, may be located (e.g., formed) on the planarization layer 59. A pixel defining layer 60 may be formed of an organic material to cover the pixel electrode 61. An opening may be formed in the pixel defining layer 60, and then an organic layer 62 may be formed on a surface of the pixel defining layer 60 and on a surface of the pixel electrode 61 exposed through the opening. The organic layer 62 may include an emission layer (or light emission layer). The present invention is not limited to the structure of the organic light-emitting display device described above, and various structures of organic light-emitting display devices may be applied to embodiments of the present invention.

The OLED displays image information by emitting red, green or blue light according to a current that is applied thereto. The OLED may include the pixel electrode 61, which is connected to the drain electrode 57 of the TFT and to which a positive power voltage is applied, a counter electrode 63, which is formed covering the entire sub-pixel (e.g., all of the sub-pixels) and to which a negative power voltage is applied, and the organic layer 62, which is disposed between the pixel electrode 61 and the counter electrode 63 to emit light.

The pixel electrode 61 and the counter electrode 63 are insulated from each other by the organic layer 62, and respectively apply voltages of opposite polarities to the organic layer 62 to induce light emission in the organic layer 62.

The organic layer 62 may include a low-molecular weight organic layer or a high-molecular weight organic layer. When a low-molecular weight organic layer is used as the organic layer 62, the organic layer 62 may have a single or multi-layer structure including at least one selected from the group consisting of a hole injection layer (HIL), a hole transport layer (HTL), an emission layer (EML), an electron transport layer (ETL), and an electron injection layer (EIL). Examples of available organic materials include copper phthalocyanine (CuPc), N,N′-di(naphthalene-1-yl)-N,N′-diphenyl-benzidine (NPB), tris-8-hydroxyquinoline aluminum (Alq3), and the like. The low-molecular weight organic layer may be formed by vacuum deposition, for example.

When a high-molecular weight organic layer is used as the organic layer 62, the organic layer 62 may mostly have a structure including an HTL and an EML. In this case, the HTL may be formed of poly(ethylenedioxythiophene) (PEDOT), and the EML may be formed of polyphenylenevinylenes (PPVs) or polyfluorenes. The HTL and the EML may be formed by screen printing, inkjet printing, or the like.

The organic layer 62 is not limited to the organic layers described above, and may be embodied in various ways known to those skilled in the art.

The pixel electrode 61 may operate as an anode, and the counter electrode 63 may operate as a cathode. Alternatively, the pixel electrode 61 may operate as a cathode, and the counter electrode 63 may operate as an anode.

The pixel electrode 61, for example, may be formed as a transparent electrode or a reflective electrode. Such a transparent electrode may be formed of indium tin oxide (ITO), indium zinc oxide (IZO), zinc oxide (ZnO), or indium oxide (In₂O₃). Such a reflective electrode, for example, may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer of ITO, IZO, ZnO, or In₂O₃ on the reflective layer.

The counter electrode 63 may be formed as a transparent electrode or a reflective electrode. When the counter electrode 63 is formed as a transparent electrode, the counter electrode 63 may function as a cathode. To this end, such a transparent electrode, for example, may be formed by depositing a metal having a low work function, such as lithium (Li), calcium (Ca), lithium fluoride/calcium (LiF/Ca), lithium fluoride/aluminum (LiF/AI), aluminum (Al), silver (Ag), magnesium (Mg), or a compound thereof, on a surface of the organic layer 62 and forming an auxiliary electrode layer or a bus electrode line thereon using a transparent electrode forming material, such as ITO, IZO, ZnO, In₂O₃, or the like. When the counter electrode 63 is formed as a reflective electrode, the reflective layer, for example, may be formed by depositing Li, Ca, LiF/Ca, LiF/Al, Al, Ag, Mg, or a compound thereof on the entire surface of the organic layer 62.

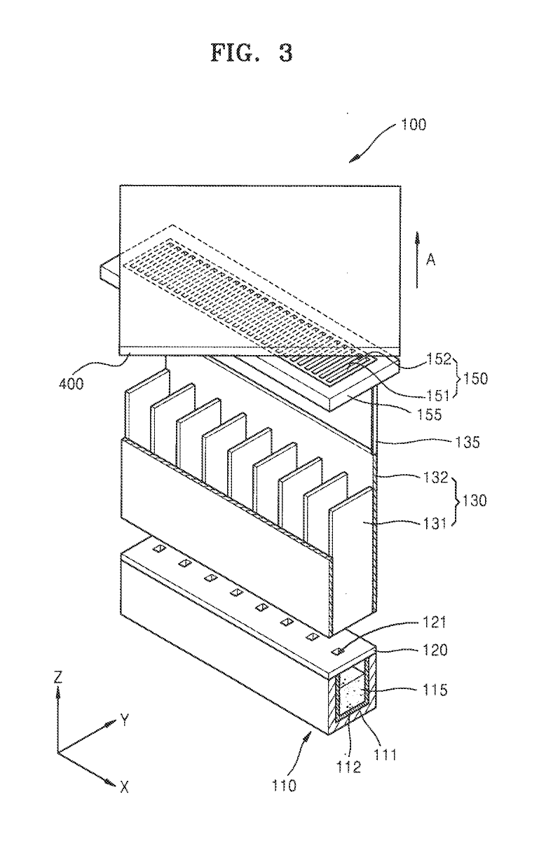

In the organic light-emitting display device described above, the organic layer 62, including the emission layer, may be formed by using a thin film deposition apparatus 100 (see FIG. 3), which will be described later.

Hereinafter, a thin film deposition apparatus according to embodiments of the present invention and a method of manufacturing an organic light-emitting display device by using the thin film deposition apparatus will be described in detail.

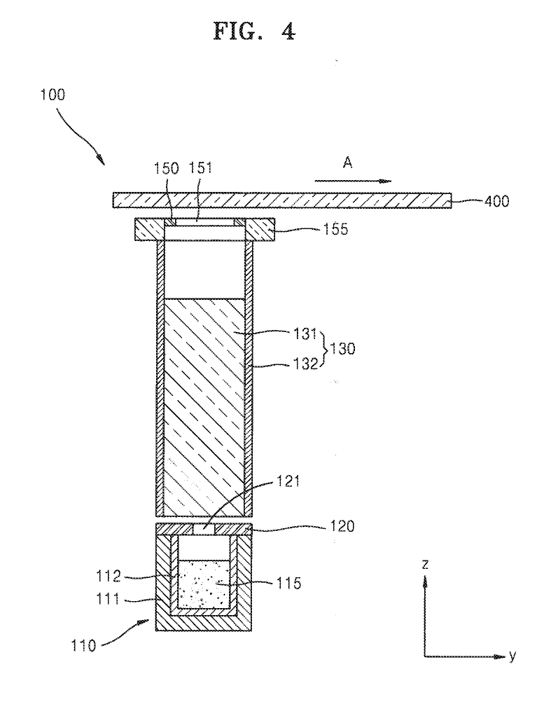

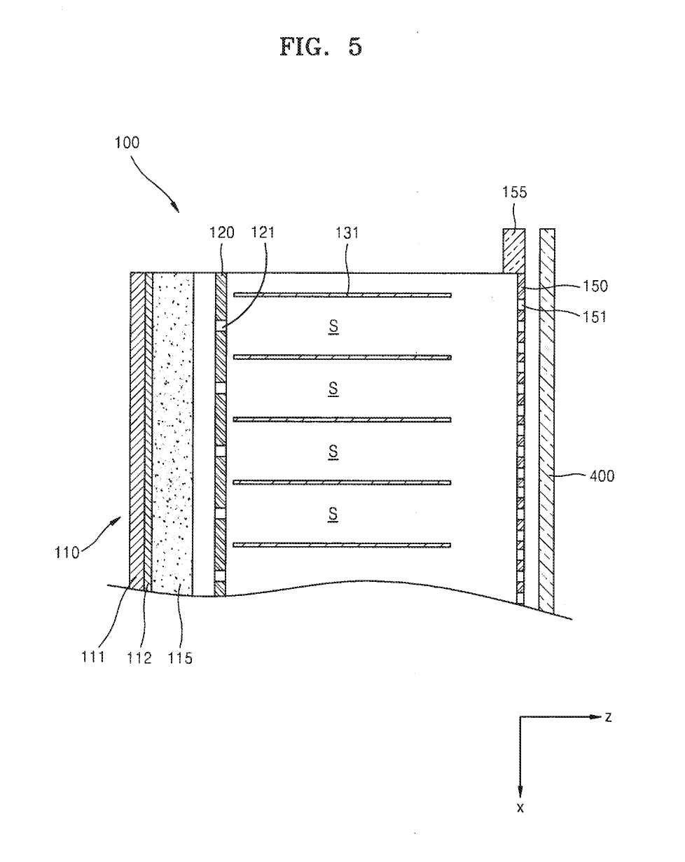

FIG. 3 is a schematic perspective view of a thin film deposition apparatus 100 according to an embodiment of the present invention; FIG. 4 is a schematic sectional view of the thin film deposition apparatus 100 illustrated in FIG. 3; and FIG. 5 is a schematic plan view of the thin film deposition apparatus 100 illustrated in FIG. 3.

Referring to FIGS. 3, 4 and 5, the thin film deposition apparatus 100 according to one embodiment of the present invention includes a deposition source 110, a deposition source nozzle unit 120, a barrier plate assembly 130, and a patterning slit sheet 150.

Although a chamber is not illustrated in FIGS. 3, 4 and 5 for convenience of explanation, all the components of the thin film deposition apparatus 100 may be located within a chamber that is maintained at an appropriate degree of vacuum. The chamber is maintained at an appropriate degree of vacuum in order to allow a deposition material to move substantially in a straight line in the thin film deposition apparatus 100.

For example, in order to deposit a deposition material 115 that is emitted from the deposition source 110 and is discharged through the deposition source nozzle unit 120 and the patterning slit sheet 150, onto a substrate 400 in a desired pattern, the chamber is in a high-vacuum state as in a deposition method using a fine metal mask (FMM). In addition, the temperatures of the barrier plate assembly 130 and the patterning slit sheet 150 are sufficiently lower than the temperature of the deposition source 110 to maintain a space between the deposition source nozzle unit 120 and the patterning slit sheet 150 in a high-vacuum state. In this regard according to one embodiment, the temperatures of the barrier plates 131 and the patterning slit sheet 150 may be about 100° C. or less. This is because the deposition material 115 that collides with the barrier plate assembly 130 may not vaporize again when the temperatures of the barrier plate assembly 130 and the patterning slit sheet 150 are sufficiently low. In addition, thermal expansion of the patterning slit sheet 150 may be reduced or minimized when the temperature of the patterning slit sheet 150 is sufficiently low. The barrier plate assembly 130 faces the deposition source 110 which is at a high temperature. In addition, the temperature of a portion of the barrier plate assembly 130 close to the deposition source 110 rises to a maximum of about 167° C. in one embodiment, and thus a partial-cooling apparatus may be further included if needed. To this end, the barrier plate assembly 130 may include a cooling member (not shown).

The substrate 400, which constitutes a deposition target on which a deposition material 115 is to be deposited, is also located in the chamber. The substrate 400 may be a substrate for flat panel displays. A large substrate, such as a mother glass, for manufacturing a plurality of flat panel displays, may be used as the substrate 160. Other substrates may also be employed.

In one embodiment of the present invention, deposition may be performed while the substrate 400 or the thin film deposition apparatus 100 is moved relative to the other.

For example, in a conventional FMM deposition method, the size of the FMM is equal to the size of a substrate. Thus, the size of the FMM is typically increased as the substrate becomes larger. However, it is neither straightforward to manufacture a large FMM nor to extend an FMM to be accurately aligned with a pattern.

In order to overcome this problem, in the thin film deposition apparatus 100 according to one embodiment of the present invention, deposition may be performed while the thin film deposition apparatus 100 or the substrate 400 is moved relative to the other. In other words, deposition may be continuously performed while the substrate 400, which is arranged facing the thin film deposition apparatus 100, is moved in a direction A. That is to say, deposition may be performed in a scanning manner. Although the substrate 400 is illustrated as being moved in the direction A in FIG. 3 when deposition is performed, embodiments or aspects of the present invention are not limited thereto. For example, deposition may be performed while the thin film deposition apparatus 100 is moved in the direction A (or in a direction opposite to the direction A) and the substrate 400 is fixed.

Thus, in the thin film deposition apparatus 100 according to one embodiment of the present invention, the patterning slit sheet 150 may be smaller (e.g., significantly smaller) than a FMM used in a conventional deposition method. In other words, in the thin film deposition apparatus 100, deposition is continuously performed, i.e., in a scanning manner while the substrate 400 is moved in the direction A. Thus, a length of the patterning slit sheet 150 in the Y-axis direction may be significantly less than a length of the substrate 400 provided a width of the patterning slit sheet 150 in the X-axis direction and a width of the substrate 400 in the X-axis direction are substantially equal to each other. As described above, since the patterning slit sheet 150 may be formed to be smaller (e.g., significantly smaller) than a FMM used in a conventional deposition method, it is relatively easy to manufacture the patterning slit sheet 150 used in the described embodiment of the present invention. In other words, using the patterning slit sheet 150, which is smaller than a FMM used in a conventional deposition method, is more convenient in all processes, including etching and other subsequent processes, such as precise extension, welding, moving, and cleaning processes, compared to the conventional deposition method using the larger FMM. This is more desirable (or advantageous) for a relatively large display device.

In order to perform deposition while the thin film deposition apparatus 100 or the substrate 400 is moved relative to the other as described above, the thin film deposition apparatus 100 and the substrate 400 may be separated from each other (e.g., by a predetermined distance), as will be described later in detail.

The deposition source 110 that contains and heats the deposition material 115 may be disposed at a side of the chamber opposite to a side at which the substrate 400 is located. While the deposition material 115 contained in the deposition source 110 is vaporized, the deposition material 115 may be deposited on the substrate 400.

For example, the deposition source 110 may include a crucible 111 that is filled with the deposition material 115, and a heater 112 that heats the crucible 111 to vaporize the deposition material 115, which is contained in the crucible 111, towards one side of the crucible 111, and in particular, towards the deposition source nozzle unit 120.

The deposition source nozzle unit 120 may be located at one side of the deposition source 110, and in particular, at the side of the deposition source 110 facing the substrate 400. The deposition source nozzle unit 120 may include a plurality of deposition source nozzles 121 arranged at equal intervals (e.g., regular intervals) in the X-axis direction. The deposition material 115 that is vaporized in the deposition source 110 passes through the deposition source nozzle unit 120 towards the substrate 400.

The barrier plate assembly 130 may be located at a side of the deposition source nozzle unit 120. The barrier plate assembly 130 may include a plurality of barrier plates 131, and a barrier plate frame 132 that covers sides of the barrier plates 131. The plurality of barrier plates 131 may be arranged parallel to each other at equal intervals (e.g., regular intervals) in the X-axis direction. In addition, each of the barrier plates 131 may be arranged parallel to a Y-Z plane in FIG. 3, i.e., perpendicular to the X-axis direction. The plurality of barrier plates 131 arranged as described above may partition the space between the deposition source nozzle unit 120 and the patterning slit sheet 150 into a plurality of deposition spaces S (e.g., see FIG. 5). In the thin film deposition apparatus 100 according to one embodiment of the present invention, the deposition space is divided by the barrier plates 131 into the deposition spaces S that respectively correspond to the deposition source nozzles 121 through which the deposition material 115 is discharged.

The barrier plates 131 may be respectively located between adjacent deposition source nozzles 121. In other words, each of the deposition source nozzles 121 may be located between two corresponding adjacent barrier plates 131. The deposition source nozzles 121 may be respectively located at the midpoint between the two corresponding adjacent barrier plates 131. As described above, since the barrier plates 131 partition the space between the deposition source nozzle unit 120 and the patterning slit sheet 150 into the plurality of sub-deposition spaces S, the deposition material 115 discharged through each of the deposition source nozzles 121 may not be mixed with the deposition material 115 discharged through other deposition source nozzles 121, and may pass through the patterning slits 151 so as to be deposited on the substrate 400. In other words, the barrier plates 131 guide the deposition material 115, which is discharged through the deposition source nozzles 121, to move straight, i.e., not to flow in the X-axis direction.

As described above, the deposition material 115 is forced to move straight by installing the barrier plates 131, so that a smaller shadow zone may be formed on the substrate 400, compared to a case where no barrier plates are installed. Thus, the thin film deposition apparatus 100 and the substrate 400 can be separated from each other (e.g., by a predetermined distance), as will be described later in detail.

One or more barrier plate frames 132, which may be formed on upper and lower sides of the barrier plates 131, may maintain the positions of the barrier plates 131, and may guide the deposition material 115, which is discharged through the deposition source nozzles 121, i.e., not to flow in the Y-axis direction.

Although the deposition source nozzle unit 120 and the barrier plate assembly 130 are illustrated as being separated from each other (e.g., by a predetermined distance), the present invention is not limited thereto. In order to prevent the heat emitted from the deposition source 110 from being conducted to the barrier plate assembly 130, the deposition source nozzle unit 120 and the barrier plate assembly 130 may be separated from each other (e.g., by a predetermined distance). Alternatively, if a heat insulator is located between the deposition source nozzle unit 120 and the barrier plate assembly 130, the deposition source nozzle unit 120 and the barrier plate assembly 130 may be bound together (e.g., attached to each other) with the heat insulator therebetween.

In other embodiments, the barrier plate assembly 130 may be constructed to be detachable from the thin film deposition apparatus 100. A conventional FMM deposition method has low deposition efficiency. The term “deposition efficiency” refers to the ratio of a deposition material deposited on a substrate to the deposition material vaporized from a deposition source. One conventional FMM deposition method has a low deposition efficiency of merely about 32%. Furthermore, in the conventional FMM deposition method, about 68% of organic deposition material that is not deposited on the substrate remains adhered to a deposition apparatus, and thus reusing the deposition material is not straightforward.

In order to overcome these problems, in the thin film deposition apparatus 100 according to one embodiment of the present invention, the deposition space is enclosed by using the barrier plate assembly 130, so that the deposition material 115 that remains un-deposited may be mostly deposited within the barrier plate assembly 130. Thus, since the barrier plate assembly 130 is constructed to be detachable from the thin film deposition apparatus 100, when a large amount of the deposition material 115 lies in the barrier plate assembly 130 after a long deposition process, the barrier plate assembly 130 may be detached from the thin film deposition apparatus 100 and then placed in a separate deposition material recycling apparatus in order to recover the deposition material 115. Due to the structure of the thin film deposition apparatus 100 according to the described embodiment, a reuse rate of the deposition material 115 is increased, so that the deposition efficiency is improved, and thus manufacturing costs are reduced.

The patterning slit sheet 150 and a patterning slit sheet frame 155 may be further located between the deposition source 110 and the substrate 400. The patterning slit sheet frame 155 may be formed in a lattice shape, similar to a window frame. The patterning slit sheet 150 is bound inside the patterning slit sheet frame 155. The patterning slit sheet 150 may include a plurality of patterning slits 151 and a plurality of patterning bars 152 that are alternately arranged in the X-axis direction. In other embodiments according to the present invention, the patterning slits 151 in different deposition spaces S may have different lengths, unlike the patterning slit sheet 150 illustration in FIG. 3. This is for improving the uniformity in thickness of a deposited thin film, as will be described later.

The deposition material 115 that is vaporized in the deposition source 110 may pass through the deposition source nozzle unit 120 and the patterning slit sheet 150 towards the substrate 400. The patterning slit sheet 150 may be manufactured by etching, which is the same method used in one conventional method of manufacturing an FMM, for example, a striped FMM.

In the thin film deposition apparatus 100 according to one embodiment of the present invention, the total number of patterning slits 151 may be greater than the total number of deposition source nozzles 121. In addition, there may be a greater number of patterning slits 151 than deposition source nozzles 121 disposed between two adjacent barrier plates 131.

In other words, at least one deposition source nozzle 121 may be located between each two adjacent barrier plates 131. Meanwhile, a plurality of patterning slits 151 may be located between each two adjacent barrier plates 131. The space between the deposition source nozzle unit 120 and the patterning slit sheet 150 is partitioned by the barrier plates 131 into deposition spaces S that correspond to the deposition source nozzles 121, respectively. Thus, the deposition material 115 discharged from each of the deposition source nozzles 121 may pass through a plurality of patterning slits 151 located in the sub-deposition space S corresponding to the deposition source nozzle 121, and may be then deposited on the substrate 400.

In addition, the barrier plate assembly 130 and the patterning slit sheet 150 may be separated (or spaced) from each other (e.g., by a predetermined distance). Alternatively, the barrier plate assembly 130 and the patterning slit sheet 150 may be connected by a connection member 135. The temperature of the barrier plate assembly 130 may increase to about 100° C. or higher due to the deposition source 110 of which a temperature is high. Thus, in order to prevent the heat of the barrier plate assembly 130 from being conducted to the patterning slit sheet 150, the barrier plate assembly 130 and the patterning slit sheet 150 are separated from each other (e.g., by a predetermined distance).

As described above, the thin film deposition apparatus 100 according to one embodiment of the present invention performs deposition while being moved relative to the substrate 400. In order to move the thin film deposition apparatus 100 relative to the substrate 400, the patterning slit sheet 150 is separated from the substrate 400 (e.g., by a predetermined distance). In addition, in order to prevent the formation of a relatively large shadow zone on the substrate 400 when the patterning slit sheet 150 and the substrate 400 are separated from each other, the barrier plates 131 may be arranged between the deposition source nozzle unit 120 and the patterning slit sheet 150 to force the deposition material 115 to move in a straight direction. Thus, the size of the shadow zone that may be formed on the substrate 400 may be reduced (e.g., sharply reduced).

For example, in a conventional deposition method using an FMM, deposition is performed with the FMM in close contact with a substrate in order to reduce or prevent formation of a shadow zone on the substrate. However, when the FMM is used in close contact with the substrate, the contact may cause defects. In addition, in the conventional deposition method, the size of the mask is the same as the size of the substrate since the mask cannot be moved relative to the substrate. Thus, the size of the mask increases as display devices become larger. However, it is not easy to manufacture such a large mask.

In order to overcome this problem, in the thin film deposition apparatus 100 according to one embodiment of the present invention, the patterning slit sheet 150 is arranged to be separated (or spaced) from the substrate 400 (e.g., by a predetermined distance), which may be facilitated by installing the barrier plates 131 to reduce the size of the shadow zone formed on the substrate 400.

As described above, according to one embodiment of the present invention, a mask is formed to be smaller than a substrate, and deposition is performed while the mask is moved relative to the substrate. Thus, the mask can be easily manufactured. In addition, defects caused due to the contact between a substrate and an FMM, which occur in the conventional deposition method, may be reduced or prevented. Furthermore, since it is unnecessary to position the FMM in close contact with the substrate during a deposition process, a manufacturing time may be reduced.

Hereinafter, the size of a shadow zone formed on a substrate when barrier plates are installed and the size of a shadow zone formed on a substrate when no barrier plates are installed are compared.

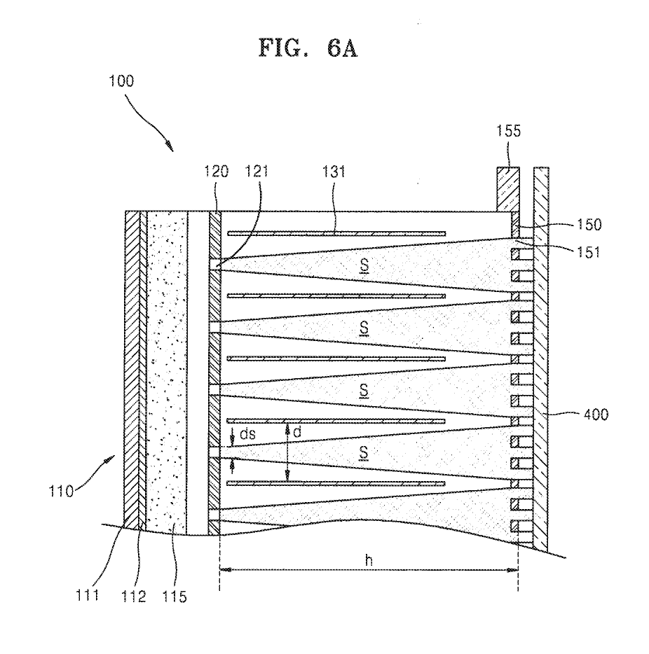

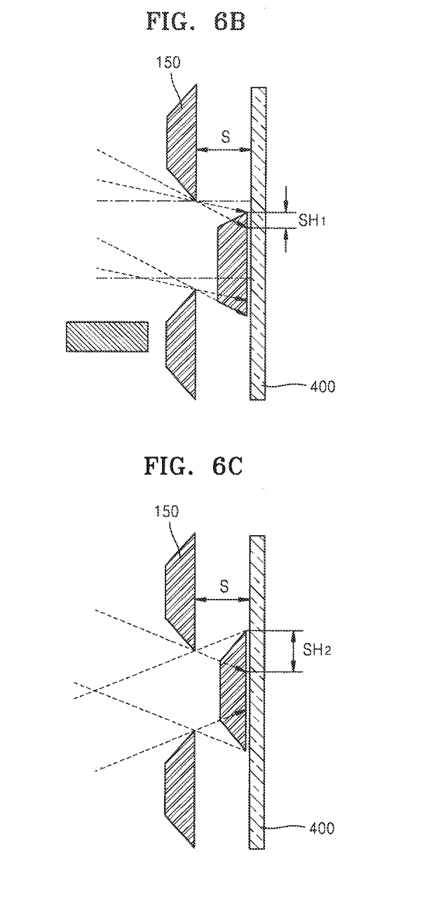

FIG. 6A is a schematic view for describing deposition of the deposition material 115 in the thin film deposition apparatus 100, according to an embodiment of the present invention. FIG. 6B illustrates a shadow zone of a thin film deposited on the substrate 400 when the deposition space is partitioned by the barrier plates 131. FIG. 6C illustrates a shadow zone of a thin film deposited on the substrate 400 when the deposition space is not partitioned.

Referring to FIG. 6A, the deposition material 115 that is vaporized in the deposition source 110 is deposited on the substrate 400 by being discharged through the deposition source nozzle unit 120 and the patterning slit sheet 150. Since the space between the deposition source nozzle unit 120 and the patterning slit sheet 150 is partitioned into a plurality of sub-deposition spaces S by the barrier plates 131, the deposition material 115 discharged through each of the deposition source nozzles 121 is not mixed with the deposition material 115 discharged through the other adjacent deposition source nozzles 121 due to the barrier plates 131.

When the space between the deposition source nozzle unit 120 and the patterning slit sheet 150 is partitioned by the barrier plate assembly 130, the deposition material 115 is deposited on the substrate 400 through the patterning slit sheet 150 at an angle of about 55°-90°. In other words, the deposition material 115 passing through a patterning slit near the barrier plate assembly 130 may be incident on the substrate 400 at about 55°, and the deposition material 115 passing through a patterning slit 150 at the middle may be substantially perpendicularly incident on the substrate 400. The width SH₁ of the shadow zone formed on the substrate 400 is determined according to Equation 1.

$${SH}_{1} = \frac{s \times {d}_{s}}{h} \qquad [ Equation 1 ]$$

where s denotes a distance between the patterning slit sheet 150 and the substrate 400, dₛ denotes a width of each of the deposition source nozzles 121, and h denotes a distance between the deposition source 110 and the patterning slit sheet 150.

However, when the space between the deposition source nozzle unit 120 and the patterning slit sheet 150 is not partitioned by the barrier plates 131, as illustrated in FIG. 6C, the deposition material 115 is discharged through the patterning slit sheet 150 in a wider range of angles than in the case described with reference to FIG. 6B. This is because the deposition material 115 discharged not just through a deposition source nozzle 121 directly facing a patterning slit 151 but also through deposition source nozzles 121 other than the deposition source nozzle 121 directly facing the patterning slit 151, passes through the patterning slit 151, and is then deposited on the substrate 400. Thus, a width SH₂ of a shadow zone formed on the substrate 400 is greater (e.g., much greater) than when the deposition space is partitioned by the barrier plates 131. The width SH₂ of the shadow zone formed on the substrate 400 is determined according to Equation 2.

$${SH}_{2} = \frac{s \times 2 d}{h} \qquad [ Equation 2 ]$$

where s denotes a distance between the patterning slit sheet 150 and the substrate 400, d denotes an interval between adjacent barrier plates 131, and h denotes a distance between the deposition source 110 and the patterning slit sheet 150.

Referring to Equations 1 and 2, dₛ, which is the width of each of the deposition source nozzles 121, is a few to tens times less than d, which is the interval between the adjacent barrier plates 131, and thus the shadow zone may have a smaller width when the space between the deposition source nozzle unit 120 and the patterning slit sheet 150 is partitioned by the barrier plates 131. The width SH₂ of the shadow zone formed on the substrate 400 may be reduced by either one of the following: (1) by reducing the interval (“d”) between the adjacent barrier walls 131, (2) by reducing the distance (“s”) between the patterning slit sheet 150 and the substrate 400, or (2) by increasing the distance (“h”) between the deposition source nozzle unit 120 and the patterning slit sheet 150.

As described above, the shadow zone formed on the substrate 400 may be reduced by installing the barrier plates 131. Thus, the patterning slit sheet 150 can be separated from the substrate 400.

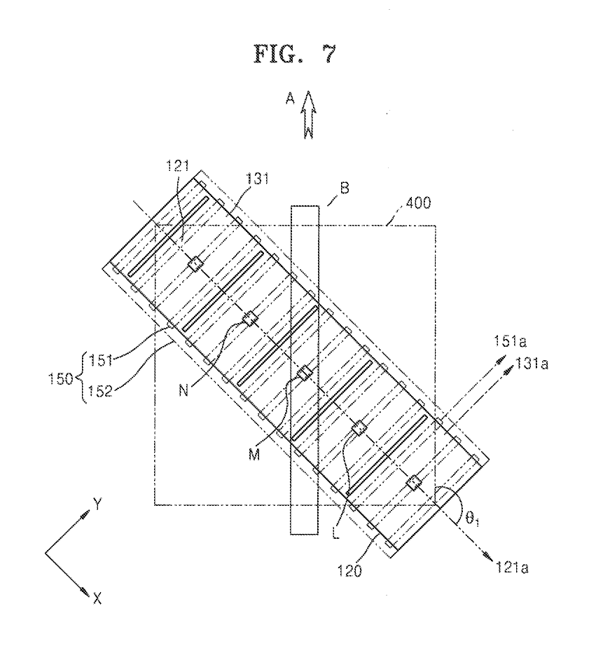

FIG. 7 is a schematic plan view illustrating an arrangement of a substrate 400, a deposition source 110, and a patterning slit sheet 150 in a thin film deposition apparatus according to an embodiment of the present invention.

Referring to FIG. 7, a direction in which deposition source nozzles 121 of a deposition source nozzle unit 120 are arranged are the same as directions in which the barrier plates 131 and the patterning slits 151 are arranged. Hereinafter, the directions in which the deposition source nozzles 121 of the deposition source nozzle unit 120, the barrier plates 131, and the patterning slits 141 are arranged are referred to as “first direction 121a”. For example, the first direction 121a may be the X-axis direction as in FIG. 7.

However, a movement direction A of the substrate 400 and the first direction 121a may cross each other. For example, an angle θ1 between the movement direction A of the substrate 400 and the first direction 121a may be greater than about 90° and less than about 180°. The directions in which the deposition source nozzles 121, the barrier plates 131, and the patterning slits 151 are arranged are identical to the first direction 121a, as described above. Thus, an angle between each of the directions in which the barrier plates 131 and the patterning slits 151 are arranged, and the movement direction A of the substrate 400 may be greater than about 90° and less than about 180°.

In addition, a lengthwise direction 131a of the barrier plates 131 and a lengthwise direction 151a of the patterning slits 151 may be the same. The lengthwise direction 131a of the barrier plates 131 (or the lengthwise direction 151a of the patterning slits 151) may be perpendicular to the first direction 121a. However, embodiments or aspects of the present invention are not particularly limited to this. For example, an angle between the lengthwise direction 131a of the barrier plates 131 and the arrangement direction (i.e., the first direction 121a) of the deposition source nozzles 121 may be greater than about 0° and less than about 180°.

When a deposition material is deposited while the substrate 400 is moved inclining at an angle with respect to the first direction 121a (i.e., the directions in which the deposition source nozzles 121, the barrier plates 131, and the patterning slits 151 are arranged (e.g., located at regular or equal intervals)), uniformity in thickness of a thin film deposited on the substrate 400 may be improved, and stitching may not occur in regions of the substrate 400 corresponding to the barrier plates 131. In other words, according to embodiments of the present invention, by moving the substrate 400 during deposition at an angle with respect to the arrangement direction 121a of the deposition source nozzles 121, the barrier plates 131 and the patterning slits 151, the formation of the thin film having less thickness on the substrate at regions corresponding to the barrier plates, may be prevented.

For example, referring to FIG. 7, the deposition material emitted from deposition source nozzles L, M, and N are deposited in a region B of the substrate 400, so that a reduction in thickness of the deposition film caused due to the barrier plates 131 may not occur.

FIG. 8 is a graph illustrating a distribution pattern of a thin film deposited on the substrate 400 by using the thin film deposition apparatus of FIG. 7.

Referring to FIG. 8, the thin film deposited on the substrate 400 has a uniform thickness without having a variation in thickness that may be caused due to the barrier plates 131.

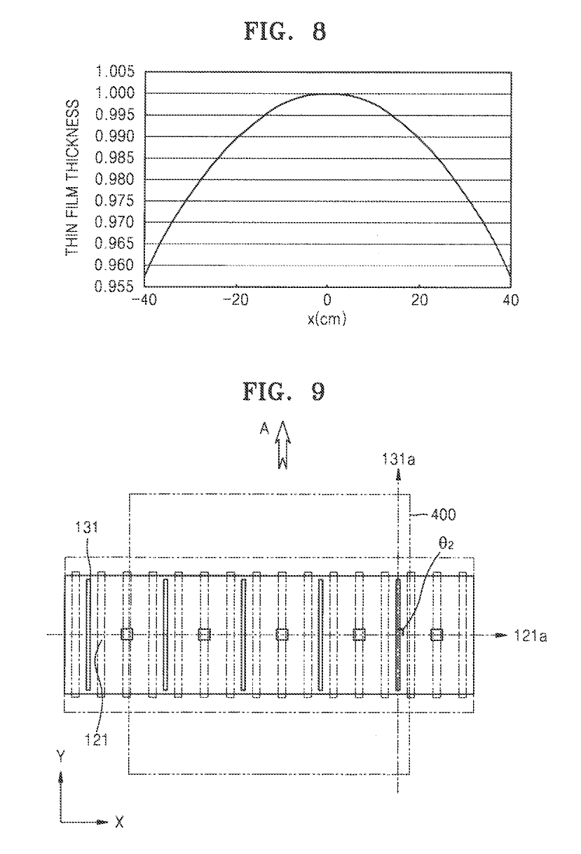

FIG. 9 is a schematic plan view of a thin film deposition apparatus according to an embodiment of the present invention in which the movement direction of the substrate 400 is perpendicular to a direction in which nozzles 121 of a deposition source 110 (see FIG. 3) is arranged (e.g., spaced at regular or equal intervals).

Referring to FIG. 9, the direction 121a in which the deposition source nozzles 121 are arranged (e.g., spaced from each other at regular or equal intervals) is perpendicular to the movement direction A of the substrate 400, which is parallel to the lengthwise direction 131a (e.g., a direction of extension parallel to the Y axis) of the barrier plates 131. If a deposition material is deposited on the substrate 400 while the deposition source nozzles 121, the barrier plates 131, and the substrate 400 are arranged as described above, a larger amount of the deposition material may be deposited in regions of the substrate 400 corresponding to the deposition source nozzles 121 than in regions of the substrate 400 corresponding to the barrier plates 131, so that a thin film deposited on the substrate 400 has a larger thickness in the regions corresponding to the deposition source nozzles 121 than in the regions corresponding to the barrier plates 131. Thus, the thin film deposited on the substrate 400 has an alternately varying thickness that is relatively thick in the regions of the substrate 400 corresponding to the deposition source nozzles 121 and relatively thin in the regions corresponding to the barrier plates 131.

FIG. 10 is a graph simulating this thickness profile of the deposition film on the substrate 400. FIG. 10 is a graph illustrating a distribution pattern of the thin film deposited on the substrate 400 by using the thin film deposition apparatus of FIG. 9.

Referring to FIG. 10, it is clear that the regions of the substrate 400 corresponding to the deposition source nozzles 121 appear as ridges (e.g., peaks) and the regions corresponding to the barrier plates 131 appear as valleys (e.g., trenches), wherein the ridges and valleys alternate. That is to say, the thin film deposited on the substrate 400 is discontinuous in the regions corresponding to the barrier plates 131, which causes stitch (e.g., boundaries or discontinuations corresponding to regions having less thickness) defects.

However, the thin film deposition apparatus of FIG. 7 according to one embodiment of the present invention allows the substrate 400 to be moved at a tilt angle greater than about 90° and less than about 180° with respect to the first direction 121a of the substrate 400 during deposition, so that discontinuous boundaries may not occur in a thin film deposited on the substrate 400, and uniformity in thickness of the thin film may be improved.

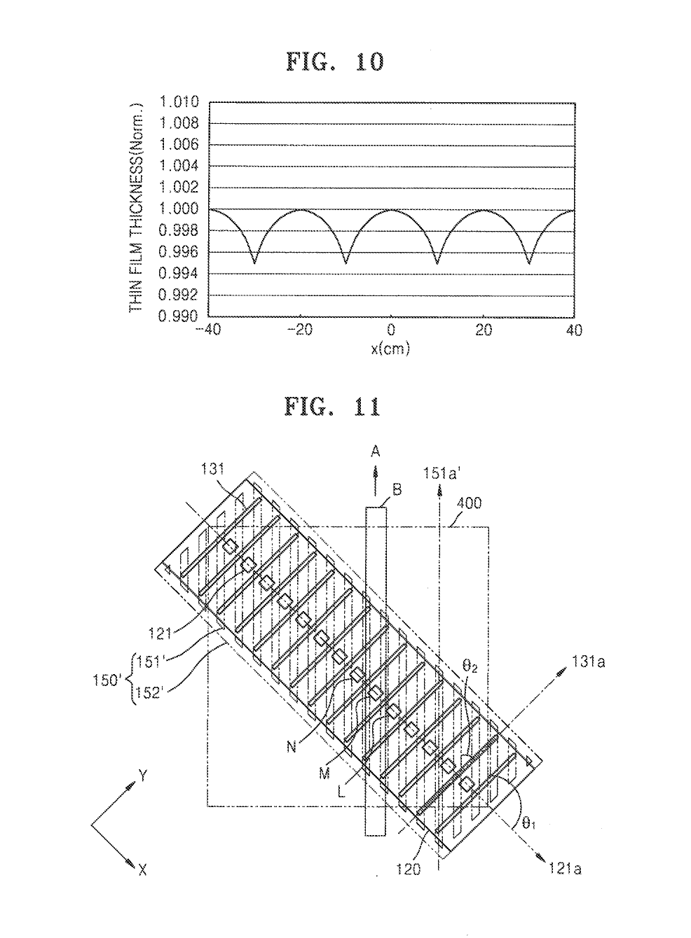

FIG. 11 is a schematic plan view illustrating an arrangement of a substrate 400, a deposition source 110, and a patterning slit sheet 150′ in a thin film deposition apparatus according to another embodiment of the present invention. The patterning slit sheet 150′ may include a plurality of patterning slits 151′ and a plurality of patterning bars 152′ that are alternately arranged (e.g., arranged in the X-axis direction).

Referring to FIG. 11, a direction 121a in which deposition source nozzles 121 of a deposition source nozzle unit 120 are arranged (e.g., spaced from each other at regular or equal intervals) are the same as directions in which the barrier plates 131 and the patterning slits 151′ are arranged (e.g., spaced from each other at regular or equal intervals). The directions in which the deposition source nozzles 121 of the deposition source nozzle unit 120, the barrier plates 131, and the patterning slits 151′ are arranged (e.g., spaced from each other at regular or equal intervals) are referred to as “first direction 121a”. For example, the first direction 121a may be the X-axis direction as in FIG. 11. However, a movement direction A of the substrate 400 and the first direction 121a may cross each other. For example, an angle θ₁ between the movement direction A of the substrate 400 and the first direction 121a may be greater than about 90° and less than about 180°. A lengthwise direction 151a′ of the patterning slits 151′ and the patterning bars 152′ is identical to the movement direction A of the substrate 400, and crosses the first direction 121a, as the movement direction A of the substrate 400. For example, an angle θ₁ between the lengthwise direction 151a′ of the patterning slits 151′ and the first angle 121a may be greater than about 90° and less than about 180°. An angle θ₂ between the lengthwise direction 151a′ of the patterning slits 151′ and the lengthwise direction 131a of the barrier plates 131a may be greater than about 0° and less than about 180°.

The embodiment illustrated in FIG. 11 differs from the embodiment of FIG. 7 in that the lengthwise direction 151a′ of the patterning slits 151′ is identical to the movement direction A of the substrate 400 and is tilted at an angle θ₁ with respect to the first direction 121a.

As described above, in one embodiment, the lengthwise direction 151a′ of the patterning slits 151′ is tilted at an angle θ₁ with respect to the first direction 121a, and the substrate 400 is moved at a tilt angle with respect to the direction in which the deposition source nozzles 121 are arranged, so that a thin film deposited on the substrate 400 may have improved thickness uniformity.

For example, referring to FIG. 11, a deposition material emitted from deposition source nozzles L and M is deposited in a region B of the substrate 400, so that a reduction in thickness of the deposition film due to the barrier plates 131 may not occur. The lengthwise direction 151a′ of the patterning slits 151′ has an angle with respect to the direction in which the deposition source nozzles 121 are arranged, but is identical to the movement direction A of the substrate 400, so that a deposition material emitted from the deposition source nozzles N is restricted not to be deposited on the region B of the substrate 400. As described above, the lengthwise direction 151a′ of the patterning slits 151′ has an angle with respect to the direction 121a in which the deposition source nozzles 121 are arranged, and deposition of a deposition material discharged from some of the deposition nozzles 121 is restricted. Thus, a thin film deposited on the substrate 400 may have improved thickness uniformity.

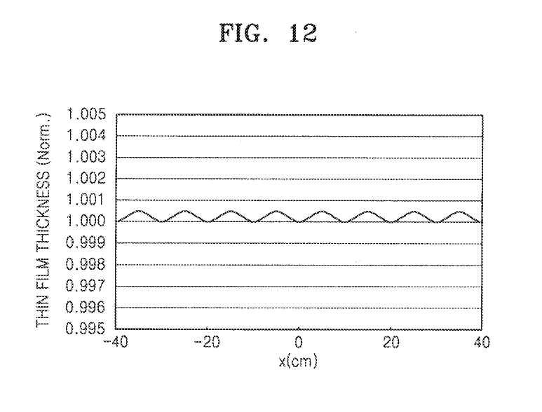

FIG. 12 is a graph illustrating a distribution pattern of a thin film deposited on the substrate 400 by using the thin film deposition apparatus of FIG. 11.

Referring to FIG. 12, the thin film deposited on the substrate 400 is found to have improved thickness uniformity. The thin film deposited on the substrate 400 appears to have valley and ridge regions with different thicknesses. However, a thickness difference between the valley and ridge regions is less than about 0.5%, which indicates a remarkable improvement in thickness uniformity.

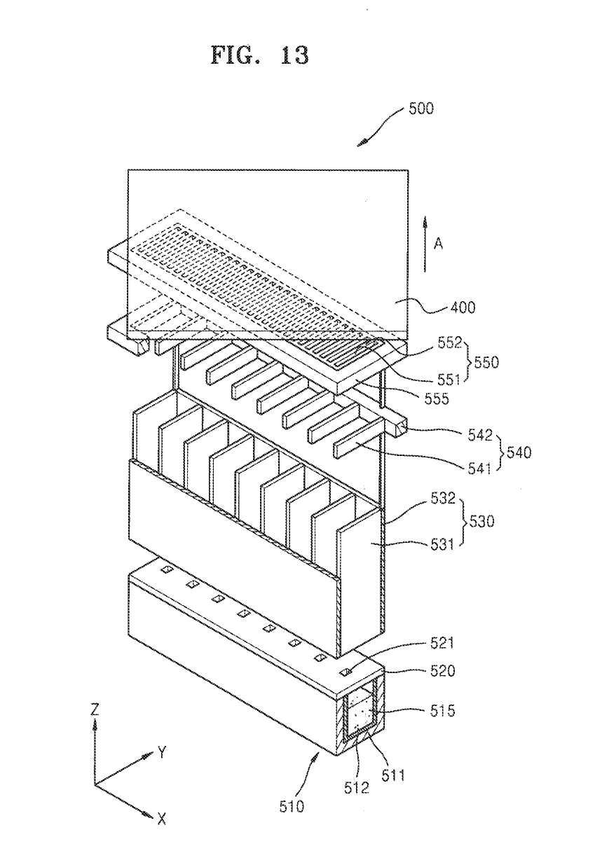

FIG. 13 is a schematic perspective view of a thin film deposition apparatus 500 according to another embodiment of the present invention.

Referring to FIG. 13, the thin film deposition apparatus 500 according to described embodiment of the present invention includes a deposition source 510, a deposition source nozzle unit 520, a first barrier plate assembly 530, a second barrier plate assembly 540, and a patterning slit sheet 550, and is used form a thin film on a substrate 400.

Although a chamber is not illustrated in FIG. 13 for convenience of explanation, all the components of the thin film deposition apparatus 500 may be located within a chamber that is maintained at an appropriate degree of vacuum. The chamber is maintained at an appropriate degree of vacuum in order to allow a deposition material to move substantially in a straight line in the thin film deposition apparatus 500.

The substrate 400, on which the deposition material 515 is to be deposited, may also be located in the chamber. The deposition source 510 that contains and heats the deposition material 515 is located at a side of the chamber opposite to a side at which the substrate 400 is located. The deposition source 510 may include a crucible 511 and a heater 512.

The deposition source nozzle unit 520 may be located at a side of the deposition source 510, for example, at the side of the deposition source 510 facing the substrate 400. The deposition source nozzle unit 520 may include a plurality of deposition source nozzles 521 arranged at equal intervals (e.g., regular intervals) in the X-axis direction.

The first barrier plate assembly 530 may be located at a side of the deposition source nozzle unit 520. The first barrier plate assembly 530 may include a plurality of first barrier plates 531, and a first barrier plate frame 532 that covers outsides of the first barrier plates 531.

The second barrier plate assembly 540 may be located at a side of the first barrier plate assembly 530. The second barrier plate assembly 540 may include a plurality of second barrier plates 541, and a second barrier plate frame 542 that covers sides of the second barrier plates 541.

A patterning slit sheet 550 and a patterning slit sheet frame 555 in which a patterning slit sheet 550 is bound (e.g., attached) may be located between the deposition source 510 and the substrate 400. The patterning slit sheet frame 555 may be formed in a lattice shape, similar to a window frame. The patterning slit sheet 550 may include a plurality of patterning slits 551 arranged (e.g., spaced at regular or equal intervals) in the X-axis direction. For example, the patterning slit sheet 550 may include the plurality of patterning slits 551 and a plurality of patterning bars 552 that are alternately arranged in the X-axis direction.

The thin film deposition assembly 500 according to the described embodiment of the present invention includes two separate barrier plate assemblies, i.e., the first barrier plate assembly 530 and the second barrier plate assembly 540, unlike the thin film deposition apparatus 100 illustrated in FIG. 3, which includes one barrier plate assembly 130.

The plurality of first barrier plates 531 may be arranged parallel to each other at equal intervals in the X-axis direction. In addition, each of the first barrier plates 531 may be arranged to extend along a Y-Z plane in FIG. 10, i.e., perpendicularly to the X-axis direction.

The plurality of second barrier plates 541 may be arranged in parallel to each other at equal intervals in the X-axis direction. In addition, each of the second barrier plates 541 may be arranged to extend in the Y-Z plane in FIG. 10, i.e., perpendicularly to the X-axis direction.

The plurality of first barrier plates 531 and second barrier plates 541 arranged as described above partition the space between the deposition source nozzle unit 520 and the patterning slit sheet 550. In the thin film deposition apparatus 500 according to the described embodiment of the present invention, the deposition space is divided by the first barrier plates 531 and the second barrier plates 541 into deposition spaces that respectively correspond to the deposition source nozzles 521 through which the deposition material 515 is discharged.

The second barrier plates 541 may be arranged to correspond respectively to the first barrier plates 531. In other words, the second barrier plates 541 may be respectively arranged to be parallel to and to be on the same plane (e.g., Y-Z plane) as the first barrier plates 531. Each pair of corresponding first and second barrier plates 531 and 541 may be located on the same plane (e.g., Y-Z plane). As described above, since the space between the deposition source nozzle unit 520 and the patterning slit sheet 550, which will be described later, is partitioned by the first barrier plates 531 and the second barrier plates 541, which are arranged in parallel to each other, the deposition material 515 discharged through each of the deposition source nozzles 521 is not mixed with the deposition material 515 discharged through the other deposition source nozzles 521, and is deposited on the substrate 400 through the patterning slits 551. In other words, the first barrier plates 531 and the second barrier plates 541 guide the deposition material 515, which is discharged through the deposition source nozzles 521, i.e., not to flow in the X-axis direction.

Although the first barrier plates 531 and the second barrier plates 541 are respectively illustrated as having the same thickness in the X-axis direction, aspects of the present invention are not limited thereto. In other words, the second barrier plates 541, which need to be accurately aligned with the patterning slit sheet 550, may be formed to be relatively thin, whereas the first barrier plates 531, which do not need to be precisely aligned with the patterning slit sheet 550, may be formed to be relatively thick, thereby facilitating the manufacture of the thin film deposition apparatus 500.

As described above, a thin film deposition apparatus according to aspects of the present invention may be easily manufactured and may be applied to manufacture large-size display devices on a mass scale simply, in view of the disclosure in the present application. The thin film deposition apparatus may improve manufacturing yield and deposition efficiency, may allow deposition materials to be reused, and may improve thickness uniformity of a thin film.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A thin film deposition apparatus for forming a thin film on a substrate, the apparatus comprising:
a deposition source for discharging a deposition material;
a deposition source nozzle unit located at a side of the deposition source, the deposition source nozzle unit having a plurality of deposition source nozzles arranged in a first direction;
a patterning slit sheet located opposite to the deposition source, the patterning slit sheet having a plurality of patterning slits arranged in the first direction; and
a barrier plate assembly comprising a plurality of barrier plates that are arranged between the deposition source nozzle unit and the patterning slit sheet in the first direction, the barrier plate assembly partitioning a space between the deposition source nozzle unit and the patterning slit sheet into a plurality of sub-deposition spaces,
wherein the thin film deposition apparatus and the substrate are movable relative to each other, and a relative movement direction between the substrate and the thin film deposition apparatus is at an angle greater than about 90° and less than about 180° with respect to the first direction.

2. The thin film deposition apparatus of claim 1, wherein a lengthwise direction of the patterning slits is substantially the same as a lengthwise direction of the barrier plates

3. The thin film deposition apparatus of claim 1, wherein a lengthwise direction of the barrier plates is substantially perpendicular to the first direction.

4. The thin film deposition apparatus of claim 1, wherein a lengthwise direction of the barrier plates is at an angle greater than about 0° and less than about 180° with respect to the first direction.

5. The thin film deposition apparatus of claim 1, wherein a lengthwise direction of the patterning slits is substantially perpendicular to the first direction.

6. The thin film deposition apparatus of claim 1, wherein a lengthwise direction of the patterning slits is substantially the same as the movement direction of the substrate.

7. The thin film deposition apparatus of claim 6, wherein a lengthwise direction of the barrier plates is substantially perpendicular to the first direction.

8. The thin film deposition apparatus of claim 6, wherein a lengthwise direction of the barrier plates is at an angle greater than about 0° and less than about 180° with respect to the first direction.

9. The thin film deposition apparatus of claim 1, wherein a lengthwise direction of the patterning slits is at an angle greater than about 90° and less than about 180° with respect to the first direction.

10. The thin film deposition apparatus of claim 1, wherein each of the barrier plates extends in a second direction that is substantially perpendicular to the first direction to partition the space between the deposition source nozzle unit and the patterning slit sheet into the plurality of sub-deposition spaces.

11. The thin film deposition apparatus of claim 1, wherein the plurality of barrier plates are arranged at equal intervals.

12. The thin film deposition apparatus of claim 1, wherein the barrier plates and the patterning slit sheet are spaced from each other.

13. The thin film deposition apparatus of claim 1, wherein the barrier plate assembly comprises a first barrier plate assembly comprising a plurality of first barrier plates, and a second barrier plate assembly comprising a plurality of second barrier plates.

14. The thin film deposition apparatus of claim 1, wherein each of the first barrier plates and each of the second barrier plates extend in a second direction that is substantially perpendicular to the first direction, to partition the space between the deposition source nozzle unit and the patterning slit sheet into the plurality of sub-deposition spaces.

15. The thin film deposition apparatus of claim 1, wherein the first barrier plates are arranged to respectively correspond to the second barrier plates.

16. The thin film deposition apparatus of claim 1, wherein each pair of corresponding said first and second barrier plates is arranged in substantially the same plane.

17. A method of manufacturing an organic light-emitting display device by using a thin film deposition apparatus for forming a thin film on a substrate, the method comprising:
arranging the substrate to be spaced from the thin film deposition apparatus; and
depositing a deposition material discharged from the thin film deposition apparatus onto the substrate while the thin film deposition apparatus or the substrate is moved relative to the other,
wherein the thin film deposition apparatus comprises:
a deposition source that discharges a deposition material; and
a deposition source nozzle unit located at a side of the deposition source and having a plurality of deposition source nozzles arranged in a first direction, and
wherein a relative movement direction between the substrate and the thin film deposition apparatus is at an angle greater than about 90° and less than about 180° with respect to the first direction.

18. The method of claim 17, wherein the depositing of the deposition material on the substrate further comprises continuously depositing the deposition material discharged from the thin film deposition apparatus on the substrate while the substrate or the thin film deposition apparatus is moved relative to the other.

19. The method of claim 17, wherein the thin film deposition apparatus further comprises:
a patterning slit sheet located opposite to the deposition source, the patterning slit sheet having a plurality of patterning slits arranged in the first direction; and
a barrier plate assembly comprising a plurality of barrier plates that are arranged between the deposition source nozzle unit and the patterning slit sheet in the first direction, the barrier plate assembly partitioning a space between the deposition source nozzle unit and the patterning slit sheet into a plurality of sub-deposition spaces.

20. The method of claim 19, wherein a lengthwise direction of the barrier plates is substantially perpendicular to the first direction.

21. The method of claim 19, wherein a lengthwise direction of the barrier plates is at an angle greater than about 0° and less than about 180° with respect to the first direction.

22. The method of claim 17, wherein a lengthwise direction of the patterning slits is substantially the same as a lengthwise direction of the barrier plates.

23. The method of claim 17, wherein a lengthwise direction of the barrier plates is substantially perpendicular to the first direction.

24. The method of claim 17, wherein a lengthwise direction of the barrier plates is at an angle greater than about 0° and less than about 180° with respect to the first direction.

25. The method of claim 17, wherein a lengthwise direction of the patterning slits is substantially perpendicular to the first direction.

26. The method of claim 17, wherein a lengthwise direction of the patterning slits is substantially the same as the movement direction of the substrate.

27. The method of claim 17, wherein a lengthwise direction of the patterning slits is at an angle greater than about 90° and less than about 180° with respect to the first direction.
